(19) United States
(12) Patent Application Publication
(10) Pub. No.: US 2016/0056137 A1
(43) Pub. Date: Feb. 25, 2016

(54) SEMICONDUCTOR CHIP AND ELECTRONIC COMPONENT

(71) Applicant: Kabushiki Kaisha Toshiba, Tokyo (JP)

(72) Inventor: Masakazu Kobayashi, Kanazawa Ishikawa (JP)

(21) Appl. No.: 14/639,421

(22) Filed: Mar. 5, 2015

(30) Foreign Application Priority Data
Aug. 19, 2014 (JP) 2014-166442

(51) Int. Cl. H01L 25/18; H01L 23/31; H01L 29/423; H01L 23/00; H01L 29/78; H01L 29/417

(52) U.S. Cl. CPC H01L 25/18; H01L 29/7827; H01L 29/41741; H01L 29/4236; H01L 24/32; H01L 23/3142; H01L 2224/32227; H01L 2924/1203; H01L 2924/1306; H01L 2924/13055

(57) ABSTRACT

According to one embodiment, a semiconductor chip includes: a semiconductor layer; an upper electrode provided on the semiconductor layer; and a lower electrode provided under the semiconductor layer, the lower electrode being under an active region of the semiconductor layer, the lower electrode not being under a termination region of the semiconductor layer, an element being disposed in the active region, and the termination region being beside the active region.

### CROSS-REFERENCE TO RELATED APPLICATIONS

This application is based upon and claims the benefit of priority from Japanese Patent Application No. 2014-166442, filed on Aug. 19, 2014; the entire contents of which are incorporated herein by reference.

### FIELD

Embodiments described herein relate generally to a semiconductor chip and an electronic component.

### BACKGROUND

In an electronic component in which a semiconductor chip is mounted on a substrate, in general, the semiconductor chip is bonded to the substrate by soldering. At this time, in some cases, solder material overflows from a space between the semiconductor chip and the substrate. Herein, when a plurality of semiconductor chips are mounted on a substrate, the space between adjacent semiconductor chips becomes narrower as the sizes of the chips become larger. When such narrowing occurs, in some cases, the overflowing solder materials between the adjacent semiconductor chips are linked to each other. When the solder materials are linked to each other between the adjacent semiconductor chips, in some cases, the film thicknesses of the solder materials become non-uniform.

When the film thicknesses of the solder materials become non-uniform, heat resistance between the semiconductor chips and the substrate becomes non-uniform, and therefore, heat generated from the semiconductor chips is not uniformly radiated to the substrate side. As a result, there is a possibility that the semiconductor chips may peel off or be damaged.

### BRIEF DESCRIPTION OF THE DRAWINGS

FIG. 1A is a schematic plan view showing a portion of an electronic component according to a first embodiment and FIG. 1B is a schematic cross-sectional view showing a portion of the electronic component according to the first embodiment;

FIG. 2A is a schematic plan view showing the electronic component according to the first embodiment and FIG. 2B is a schematic cross-sectional view showing a portion of the electronic component according to the first embodiment;

FIG. 3 is a schematic cross-sectional view showing a portion of a cross section of an active region of a semiconductor chip according to the first embodiment;

FIG. 4A and FIG. 4B are schematic cross-sectional views showing an action of the electronic component according to a reference example;

FIG. 5A is a schematic cross-sectional view showing an action of the semiconductor chip according to the reference example and FIG. 5B is a schematic cross-sectional view showing an action of the semiconductor chip according to the first embodiment;

FIG. 6A is a schematic cross-sectional view showing an action of the semiconductor chip according to the first embodiment and FIG. 6B is a view showing current-voltage curves of the semiconductor chip according to first embodiment and the semiconductor chip according to the reference example;

FIG. 7A is a schematic plan view showing a portion of an electronic component according to a second embodiment and FIG. 7B is a schematic cross-sectional view showing a portion of the electronic component according to the second embodiment;

FIG. 8A is a schematic plan view showing a portion of an electronic component according to a third embodiment and FIG. 8B is a schematic cross-sectional view showing a portion of the electronic component according to the third embodiment; and

FIG. 9A is a schematic cross-sectional view showing a portion of an electronic component according to a fourth embodiment and FIG. 9B is a schematic cross-sectional view showing a portion of the electronic component according to the first embodiment.

### DETAILED DESCRIPTION

In general, according to one embodiment, a semiconductor chip includes: a semiconductor layer; an upper electrode provided on the semiconductor layer; and a lower electrode provided under the semiconductor layer, the lower electrode being under an active region of the semiconductor layer, the lower electrode not being under a termination region of the semiconductor layer, an element being disposed in the active region, and the termination region being beside the active region.

Hereinafter, embodiments will be described with reference to accompanying drawings. In the following description, the same reference numerals will be given to identical members and the repeated description thereof will be appropriately omitted.

### First Embodiment

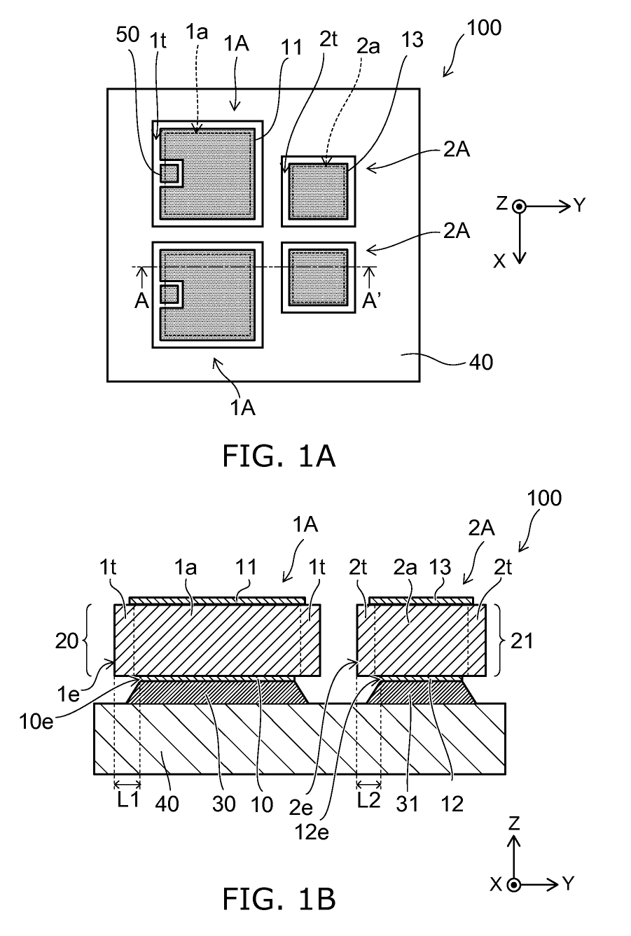

FIG. 1A is a schematic plan view showing a portion of an electronic component according to a first embodiment and FIG. 1B is a schematic cross-sectional view showing a portion of the electronic component according to the first embodiment.

Herein, a cross section taken at a position along line A-A′ of FIG. 1A is shown in FIG. 1B. A wire that links semiconductor chips or the like or a sealing resin that seals the semiconductor chips is not shown in FIG. 1A and FIG. 1B.

An electronic component 100 according to the first embodiment includes a plurality of semiconductor chips 1A and 2A, a plurality of bonding members 30 and 31, a substrate 40, and a sealing resin 60 to be described later.

In the electronic component 100, a plurality of semiconductor chips 1A and a plurality of semiconductor chips 2A are provided on the substrate 40. The semiconductor chips 1A and 2A are semiconductor chips with a vertical electrode structure.

The semiconductor chip 1A has, for example, an insulated gate bipolar transistor (IGBT), a metal-oxide-semiconductor field-effect transistor (MOSFET), or a parasitic diode. The semiconductor chip 2A has, for example, a freewheeling diode (FWD).

In the semiconductor chip 1A, an upper electrode 11 is provided on a semiconductor layer 20. The semiconductor layer 20 includes semiconductor and may include insulator or metal and so on. The upper electrode 11 is, for example, an emitter electrode of an IGBT or a source electrode of a MOSFET. Elements such as a MOS-type transistor and a parasitic diode are disposed in an active region 1a of the semiconductor layer 20. In addition, a termination region 1t is provided so as to surround the active region 1a when the semiconductor chip 1A is seen from a Z-direction. In addition, an upper electrode 13 and a gate electrode 50 are provided on a semiconductor layer 20. The gate electrode 50 is also referred to as a gate pad.

In the semiconductor chip 1A, a lower electrode 10 is positioned under the semiconductor layer 20. The lower electrode 10 is a collector electrode of an IGBT or a drain electrode of a MOSFET. The lower electrode 10 is positioned under the active region 1a of the semiconductor layer 20. The lower electrode 10 is not positioned under the termination region 1t of the semiconductor layer 20. The area of the lower electrode 10 is smaller than the area of the upper electrode 11. The thickness of the lower electrode 10 is, for example, 1 μm.

In the semiconductor chip 2A, the upper electrode 13 is an anode electrode of an FWD. Elements such as a p-n diode and a p-i-n diode are disposed in an active region 2a of the semiconductor layer 21. The semiconductor layer 21 includes semiconductor and may include insulator or metal and so on. In addition, a termination region 2t is provided so as to surround the active region 2a when the semiconductor chip 2A is seen from a Z-direction. The semiconductor layer 21 has a p-type semiconductor region, an n-type semiconductor region, an interlayer insulation film, and the like.

In the semiconductor chip 2A, a lower electrode 12 is positioned under the semiconductor layer 21. The lower electrode 12 is a cathode electrode of an FWD. The lower electrode 12 is positioned under the active region 2a of the semiconductor layer 21. The lower electrode 12 is not positioned under the termination region 2t of the semiconductor layer 21. The area of the lower electrode 12 is smaller than the area of the upper electrode 13. The thickness of the lower electrode 12 is, for example, 1 μm.

The bonding member 30 is provided between the substrate 40 and the lower electrode 10. The bonding member 31 is provided between the substrate 40 and the lower electrode 10. The bonding members 30 and 31 are, for example, solder materials. The thicknesses of the bonding members 30 and 31 are, for example, 50 μm.

When the lower electrode is disposed on the entire area of the lower side of the semiconductor layer, in some cases, the bonding member overflows from a space between the semiconductor chip and the substrate 40. Herein, the distance at which the bonding member overflows from the position of the side surface of the semiconductor layer in a direction parallel to an upper surface of the substrate 40 is defined as an “overflowing length”.

In the semiconductor chip 1A, a distance L1 from an end portion 1e of the semiconductor chip 1A to an end portion 10e of the lower electrode 10 is set to be longer than the “overflowing length”. In addition, also in the semiconductor chip 2A, a distance L2 from an end portion 2e of the semiconductor chip 2A to an end portion 12e of the lower electrode 12 is set to be longer than the “overflowing length”. The distances L1 and L2 are, for example, not less than 0.3 mm.

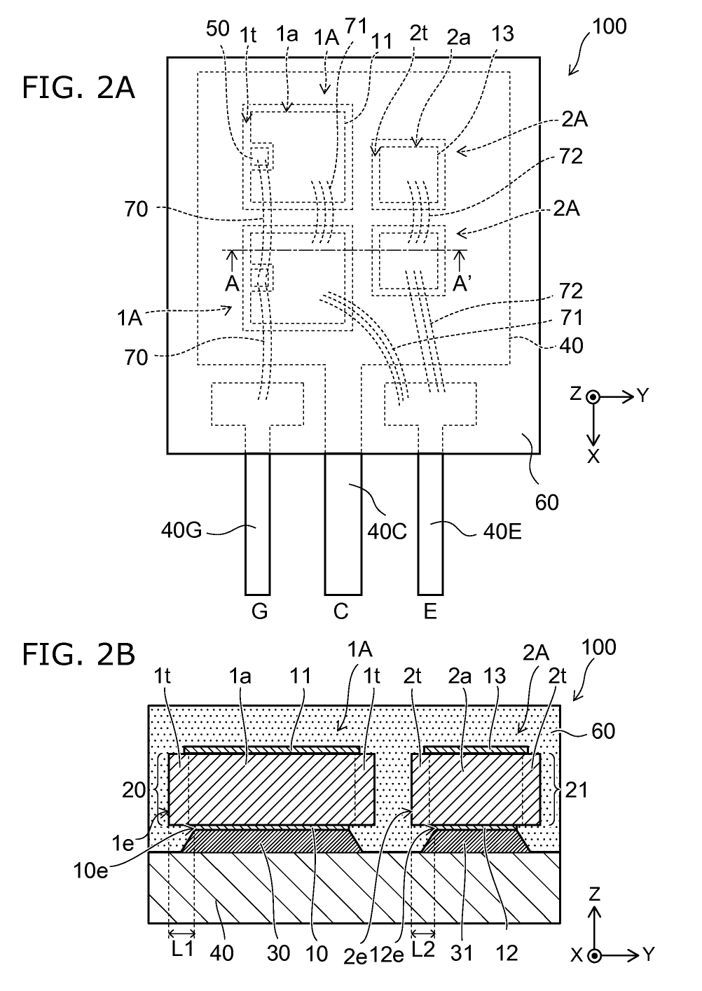

FIG. 2A is a schematic plan view showing an electronic component according to the first embodiment and FIG. 2B is a schematic cross-sectional view showing a portion of the electronic component according to the first embodiment. Herein, a cross section at a position taken along line A-A′ of FIG. 2A is shown in FIG. 2B.

The electronic component 100 shown in FIG. 2A and FIG. 2B in the case in which the semiconductor chip 1A is an IGBT will be described as an example.

In the electronic component 100, a lead 40C for a collector extends from the substrate 40. The lead 40C may be included in the substrate 40 and may be regarded as the substrate 40. Furthermore, the electronic component 100 has a lead 40G for a gate and a lead 40E for an emitter. In this manner, the electronic component 100 is an electronic component having three terminals.

The lead 40G is electrically connected to the gate electrode 50 of the semiconductor chip 1A via a wire 70. The lead 40E is electrically connected to the upper electrode 11 of the semiconductor chip 1A via a wire 71. Furthermore, the lead 40E is electrically connected to the upper electrode 13 of the semiconductor chip 2A via a wire 72.

At least a portion of the substrate 40, at least a portion of the lead 40G, at least a portion of the lead 40E, a plurality of the semiconductor chips 1A and 2A, a plurality of the bonding members 30 and 31, and a plurality of wires 70 to 72 are sealed with the sealing resin 60.

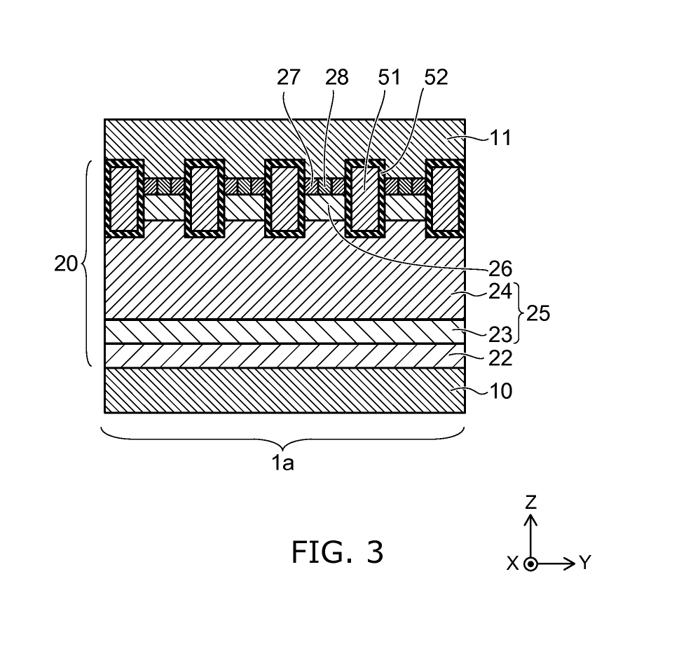

FIG. 3 is a schematic cross-sectional view showing a portion of a cross section of the active region of the semiconductor chip according to the first embodiment.

In FIG. 3, an IGBT is exemplified as a cross section of an active region 1a of a semiconductor chip 1A.

In the active region 1a, an n-type semiconductor region 25 (first semiconductor region) is provided between an upper electrode 11 and a lower electrode 10. The semiconductor region 25 has an n⁺-type buffer region 23 and a base region 24 provided on the buffer region 23. A p⁺-type collector region 22 (second semiconductor region) is provided between the lower electrode 10 and the semiconductor region 25.

A p⁺-type base region 26 (third semiconductor region) is provided between the upper electrode 11 and the semiconductor region 25. An n⁺-type emitter region 27 (fourth semiconductor region) is provided between the upper electrode 11 and the base region 26. In addition, a p⁺-type semiconductor region 28 is provided between the upper electrode 11 and the base region 26. A gate electrode 51 is provided on the semiconductor region 25, the base region 26, and the emitter region 27 via an insulating film 52.

In this manner, an IGBT element including an emitter, a base, a collector, and a gate is disposed in the active region 1a. The collector region 22 is removed from FIG. 3 in the case in which the semiconductor chip 1A has a MOSFET instead of the IGBT. In addition, in the case of the MOSFET, the lower electrode 10 is in contact with the semiconductor region 25. In addition, the emitter region 27 is referred to as a source region and the buffer region 23 is referred to as a drain region. In addition, a p-type semiconductor region, an n-type semiconductor region, an intrinsic semiconductor region, and the like are provided in an active region 2a, and a p-n diode and a p-i-n diode are disposed in the active region 2a.

The materials of the substrate 40, the lead 40C, the lead 40G, and the lead 40E are, for example, copper (Cu). The semiconductors included in the semiconductor layers 20 and 21 are, for example, at least one selected from silicon (Si), silicon carbide (SiC), gallium nitride (GaN), and the like.

The materials of the lower electrodes 10 and 12 and the gate electrode 50 are, for example, at least one selected from aluminum (Al), titanium (Ti), nickel (Ni), tungsten (W), gold (Au), and the like.

The materials of the bonding members 30 and 31 are, for example, at least one selected from tin (Sn)-lead (Pb)-based solder, tin (Sn)-silver (Ag)-copper (Cu)-based solder, tin (Sn)-zinc (Zn)-aluminum (Al)-based solder, tin (Sn)-bismuth (Bi)-silver (Ag)-based solder, and the like.

The material of the sealing resin 60 is, for example, at least one selected from epoxy resins, phenolic resins, polyethylene resins, polypropylene resins, polyvinyl chloride resins, polystyrene resins, ABS resins, acrylic resins, polycarbonate resins, and the like.

An action of an electronic component according to a reference example will be described before describing an action of the electronic component 100.

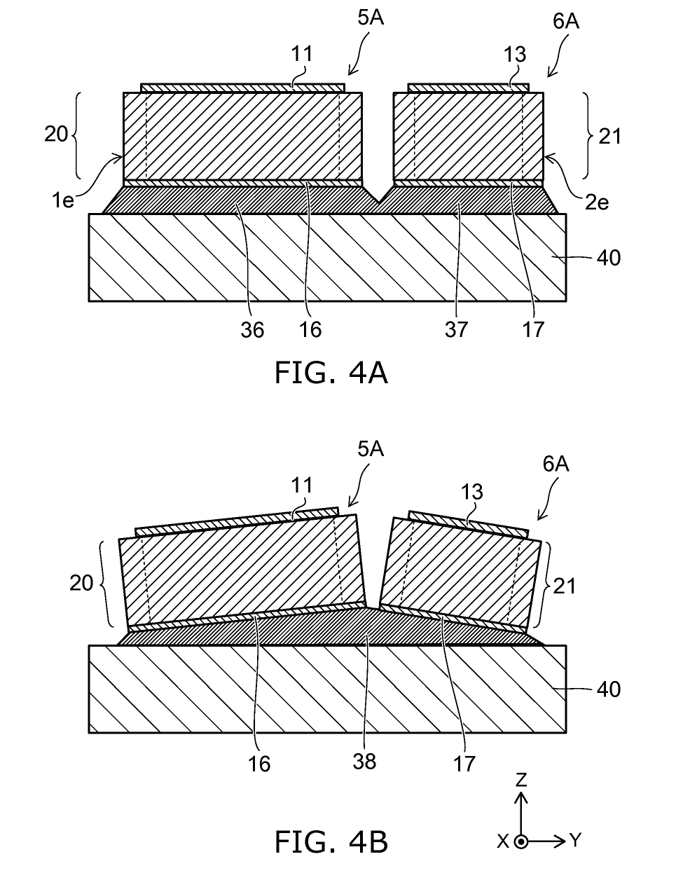

FIG. 4A and FIG. 4B are schematic cross-sectional views showing the action of the electronic component according to the reference example.

In a semiconductor chip 5A shown in FIG. 4A, a lower electrode 16 is provided on the entire area of a lower side of a semiconductor layer 20. In a semiconductor chip 6A shown in FIG. 4A, a lower electrode 17 is provided on the entire area of a lower side of a semiconductor layer 21.

Herein, the semiconductor chip 5A and the semiconductor chip 6A approach each other as the chip sizes of the semiconductor chips 5A and 6A become larger. When the entire area of the lower electrode 16 is wet with a bonding member 36 and entire area of the lower electrode 17 is wet with a bonding member 37, the bonding members 36 and 37 are caused to overflow. In some cases, the bonding members 36 and 37 are linked to each other between the semiconductor chip 5A and the semiconductor chip 6A.

The state in which the bonding members 36 and 37 are linked to each other is shown in FIG. 4A.

When the bonding members 36 and 37 are linked to each other, in some cases, the film thickness of a bonding member 38 becomes non-uniform due to surface tension of the bonding member 38 in which the bonding members 36 and 37 are linked to each other. The state in which the film thickness of the bonding member 38 becomes non-uniform is shown in FIG. 4B.

When the film thickness of the bonding member 38 becomes non-uniform, heat resistance between the semiconductor chip 5A and the substrate 40 becomes non-uniform, and therefore, heat generated from the semiconductor chip 5A is not uniformly radiated to the substrate 40 side. In addition, when the film thickness of the bonding member 38 becomes non-uniform, heat resistance between the semiconductor chip 6A and the substrate 40 becomes non-uniform, and therefore, heat generated from the semiconductor chip 6A is not uniformly radiated to the substrate 40 side.

Accordingly, in some cases, local heat accumulation occurs between the semiconductor chip 5A and the substrate 40. In addition, in some cases, local heat accumulation occurs between the semiconductor chip 6A and the substrate 40. As a result, the semiconductor chips 5A and 6A peel off from the substrate 40 or are damaged.

In contrast, the action of the electronic component 100 according to the first embodiment will be described.

In the electronic component 100 according to the first embodiment, a distance L1 from an end portion 1e of the semiconductor chip 1A to an end portion 10e of the lower electrode 10 is set to be longer than the “overflowing length”. In addition, a distance L2 from an end portion 2e of the semiconductor chip 2A to an end portion 12e of the lower electrode 12 is set to be longer than the “overflowing length”.

Accordingly, even if the entire area of the lower electrode 10 is wet with the bonding member 30 and the entire area of the lower electrode 12 is wet with the bonding member 31, the bonding members 30 and 31 are rarely caused to overflow. As a result, the bonding members 30 and 31 are rarely linked to each other between the semiconductor chip 1A and the semiconductor chip 2A which are adjacent to each other.

Accordingly, the film thicknesses of the bonding members 30 and 31 are maintained in a substantially uniform state. Accordingly, the heat resistance between the semiconductor chip 1A and the substrate 40 and the heat resistance between the semiconductor chip 2A and the substrate 40 become substantially uniform. As a result, the heat generated from the semiconductor chips 1A and 2A is almost uniformly radiated to the substrate 40 side. That is, local heat accumulation rarely occurs between the semiconductor chip 1A and the substrate 40 and local heat accumulation rarely occurs between the semiconductor chip 2A and the substrate 40. As a result, the semiconductor chips 1A and 2A rarely peel off from the substrate 40 or are rarely damaged.

In addition, the bonding members 30 and 31 rarely overflow from the space between the semiconductor chips 1A and 2A and the substrate 40, and therefore, a plurality of the respective semiconductor chips 1A can approach each other and a plurality of the respective semiconductor chips 2A can approach each other. Thus, it is possible to reduce the size of the electronic component.

An action of the semiconductor chip 1A when the semiconductor chip 1A included in the electronic component 100 according to the first embodiment has an IGBT will be described.

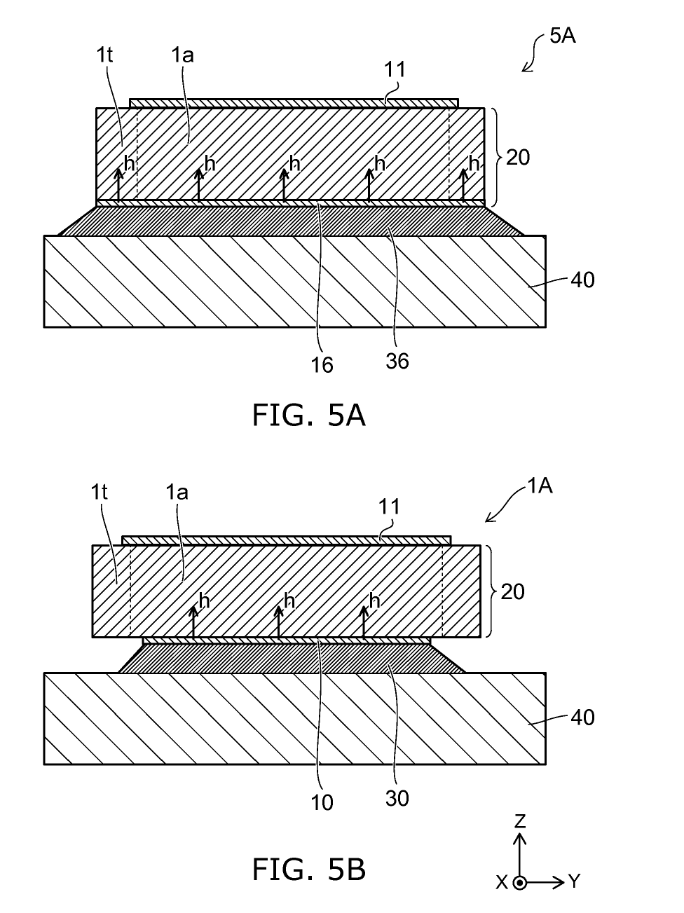

FIG. 5A is a schematic cross-sectional view showing an action of the semiconductor chip according to the reference example and FIG. 5B is a schematic cross-sectional view showing an action of the semiconductor chip according to the first embodiment.

The semiconductor chip 5A shown in FIG. 5A and the semiconductor chip 1A shown in FIG. 5B each have an IGBT.

In the semiconductor chip 5A (FIG. 5A) according to the reference example, the lower electrode 16 is provided on the entire area of the lower side of the semiconductor layer 20. In addition, the bonding member 36 is provided between the lower electrode 16 and the substrate 40. In the semiconductor chip 5A, the lower electrode 16 is provided under the active region 1a and under the termination region 1t. Accordingly, in the semiconductor chip 5A, when power is turned on, holes injected from the lower electrode 16 are easily accumulated in the termination region 1t on the lower electrode 16.

When the holes are easily accumulated in the semiconductor layer 20, a parasitic thyristor included in the semiconductor chip 5A is easily operated, and therefore, there is a possibility that a latch-up of the parasitic thyristor may occur.

In contrast, in the semiconductor chip 1A (FIG. 5B) according to the first embodiment, the lower electrode 10 is positioned under the active region 1a of the semiconductor layer 20, but is not positioned under the termination region 1t. Accordingly, in the semiconductor chip 1A, when power is turned on, holes injected from the lower electrode 16 are rarely accumulated in the termination region 1t of the semiconductor layer 20.

Accordingly, the parasitic thyristor included in the semiconductor chip 1A is rarely operated and the latch-up of the parasitic thyristor rarely occurs. That is, the latch-up resistance quantity of the semiconductor chip 1A increases compared to the latch-up resistance quantity of the semiconductor chip 5A.

Another action of the semiconductor chip 1A when the semiconductor chip 1A has an IGBT will be described.

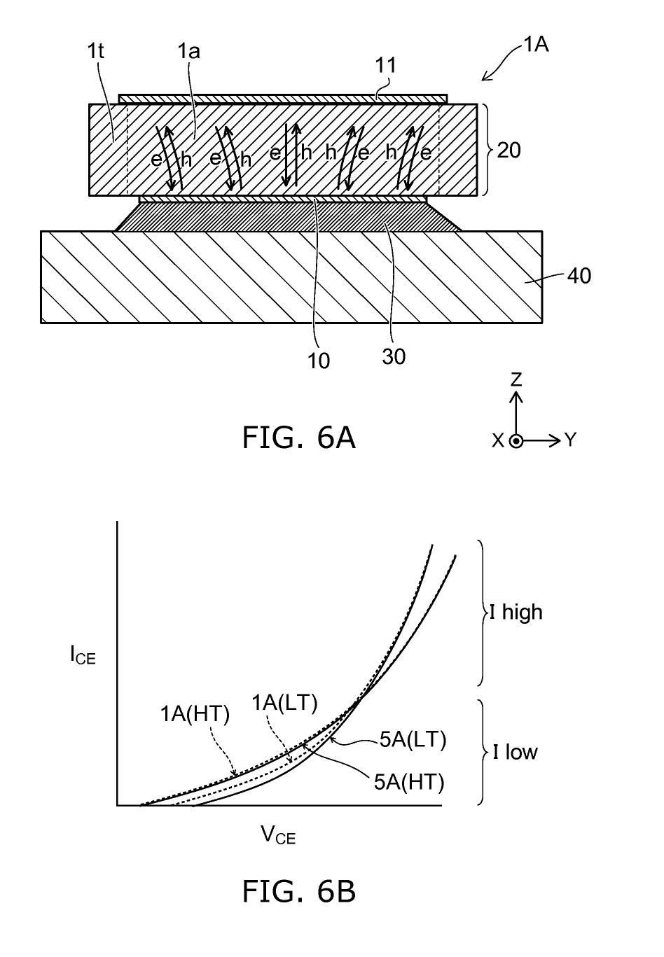

FIG. 6A is a schematic cross-sectional view showing an action of the semiconductor chip according to the first embodiment and FIG. 6B is a view showing current-voltage curves of the semiconductor chip according to first embodiment and the semiconductor chip according to the reference example.

The horizontal axis of FIG. 6B is a voltage (V_{CE}) between the lower electrode 10 and the upper electrode 11 and the longitudinal axis is a current (I_{CE}) flowing between the lower electrode 10 and the upper electrode 11.

In the semiconductor chip 1A shown in FIG. 6A, when power is turned on, electronic currents (e) introduced from the upper electrode 11 are concentrated on the lower electrode 10 having a lower area than that of the upper electrode 11.

Here, a current-voltage curve of the semiconductor chip 5A according to the reference example at a low temperature (LT) and at a high temperature (HT) is shown by a solid line in FIG. 6B. In addition, the current-voltage curve of the semiconductor chip 1A according to the first embodiment at a low temperature (LT) and at a high temperature (HT) is shown by a broken line in FIG. 6B. The low temperature (LT) is, for example, a normal temperature (25° C.). The high temperature (HT) is, for example, 150° C.

In a low current region (I_{low}) having a comparatively low current (I_{CE}), the semiconductor chips 1A and 5A show positive temperature dependency in which the current (I_{CE}) increases when temperature rises. In addition, in a high current region (I_{high}) having a comparatively high current (I_{CE}), the semiconductor chips 1A and 5A show negative temperature dependency in which the current (I_{CE}) decreases when temperature rises.

However, in the semiconductor chip 1A, when power is turned on, electronic currents (e) introduced from the upper electrode 11 are concentrated on the lower electrode 10 having a smaller area than that of the upper electrode 11, thereby flowing into the lower electrode 10. Accordingly, in the semiconductor chip 1A, the density of the electronic currents on the collector side (lower electrode 10 side) becomes higher compared to that of the semiconductor chip 5A.

Accordingly, in the low current region (I_{low}) at a low temperature, the hole injection from the collector side (lower electrode 10 side) of the semiconductor chip 1A is promoted compared to the semiconductor chip 5A. That is, in the low current region (I_{low}), the current (I_{CE}) at a low temperature in the semiconductor chip 1A increases compared to the current (I_{CE}) at a low temperature in the semiconductor chip 5A.

Meanwhile, in the low current region (I_{low}) at a high temperature, the current (I_{CE}) generally depends on the chip temperature. Accordingly, in the low current region (I_{low}) at a high temperature, there is no difference between the current (I_{CE}) of the semiconductor chip 1A and the current (I_{CE}) of the semiconductor chip 5A equivalent to that in the low current region (I_{low}) at a low temperature.

In this manner, in the semiconductor chip 1A, the rise of the current (I_{CE}) in the low current region (I_{low}) becomes larger compared to that in the semiconductor chip 5A. In other words, in the semiconductor chip 1A, a saturation current in the low current region (I_{low}) at a low temperature becomes larger.

### Second Embodiment

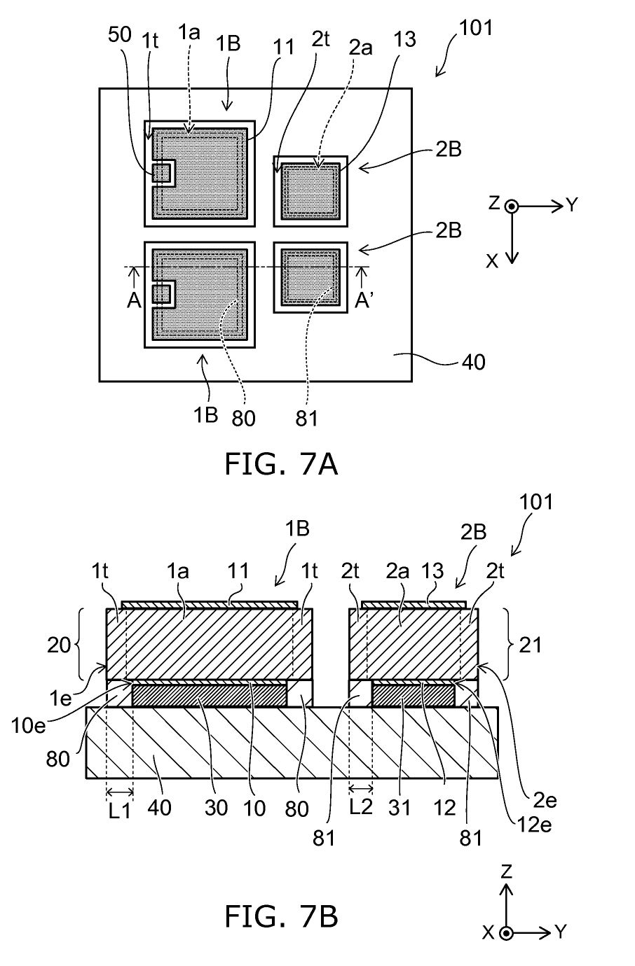

FIG. 7A is a schematic plan view showing a portion of an electronic component according to a second embodiment and FIG. 7B is a schematic cross-sectional view showing a portion of the electronic component according to the second embodiment.

Herein, a cross section at a position taken along line A-A′ of FIG. 7A is shown in FIG. 7B. In addition, a wire that links semiconductor chips or the like or a sealing resin that seals the semiconductor chips is not shown in FIG. 7A and FIG. 7B.

In an electronic component 101 according to the second embodiment, a plurality of semiconductor chips 1B and a plurality of semiconductor chips 2B are provided on a substrate 40. The semiconductor chip 1B has, for example, an IGBT or a MOSFET. The semiconductor chip 2B has, for example, an FWD

In the semiconductor chip 1B, a lower electrode 10 is positioned under a semiconductor layer 20. The lower electrode 10 is positioned under an active region 1a of the semiconductor layer 20. The lower electrode 10 is not positioned under a termination region 1t of the semiconductor layer 20. The area of the lower electrode 10 is smaller than the area of an upper electrode 11.

In the semiconductor chip 1B, a frame member 80 is provided under the semiconductor layer 20. The frame member 80 is disposed under the semiconductor layer 20 which is not provided with the lower electrode 10. The frame member 80 is in contact with the substrate 40. The thickness of the frame member 80 is greater than the thickness of the lower electrode 10. The frame member 80 includes, for example, insulating materials such as ceramics or resins. A bonding member 30 is provided between the substrate 40 and the lower electrode 10. When the semiconductor chip 1B is seen from a Z-direction, the lower electrode 10 and the bonding member 30 are surrounded by the frame member 80.

According to the semiconductor chip 1B, the bonding member 30 is surrounded by the frame member 80. Accordingly, it is more difficult for the bonding member 30 to overflow from the space between the semiconductor chip 1B and the substrate 40.

In the semiconductor chip 2B, a lower electrode 12 is positioned under a semiconductor layer 21. The lower electrode 12 is positioned under an active region 2a of the semiconductor layer 21. The lower electrode 12 is not positioned under a termination region 2t of the semiconductor layer 21. The area of the lower electrode 12 is smaller than the area of an upper electrode 13.

In the semiconductor chip 2B, a frame member 81 is provided under the semiconductor layer 21. The frame member 81 is in contact with the substrate 40. The thickness of the frame member 81 is greater than the thickness of the lower electrode 12. The frame member 81 includes, for example, insulating materials such as ceramics and resins. A bonding member 31 is provided between the substrate 40 and the lower electrode 12. When the semiconductor chip 2B is seen from a Z-direction, the lower electrode 12 and the bonding member 31 are surrounded by the frame member 81.

According to the semiconductor chip 2B, the bonding member 31 is surrounded by the frame member 81. Accordingly, it is more difficult for the bonding member 31 to overflow from the space between the semiconductor chip 2B and the substrate 40.

### Third Embodiment

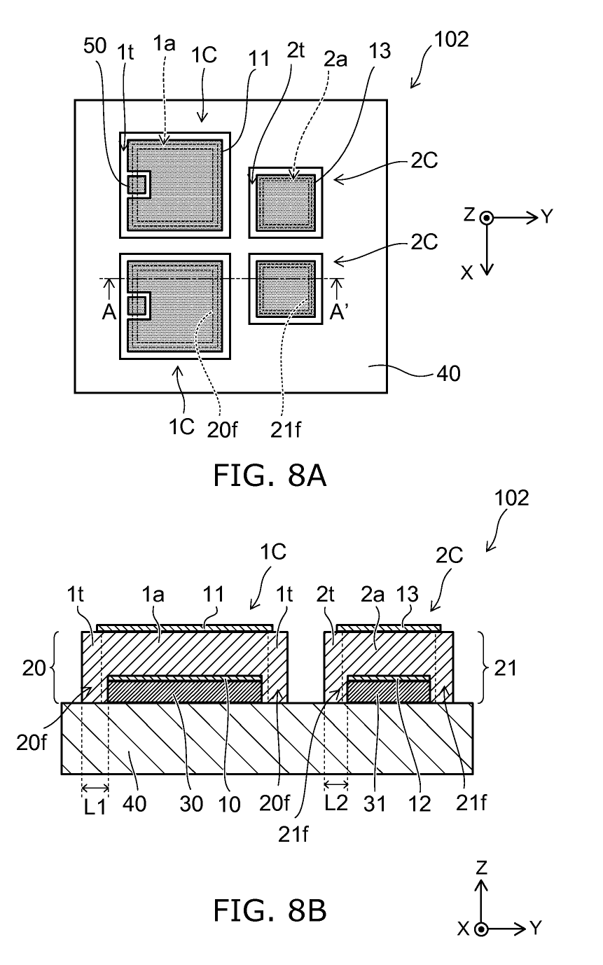

FIG. 8A is a schematic plan view showing a portion of an electronic component according to a third embodiment and FIG. 8B is a schematic cross-sectional view showing a portion of the electronic component according to the third embodiment.

Herein, a cross section at a position taken along line A-A′ of FIG. 8A is shown in FIG. 8B. In addition, a wire that links semiconductor chips or the like or a sealing resin that seals the semiconductor chips is not shown in FIG. 8A and FIG. 8B.

In an electronic component 102 according to the third embodiment, a plurality of semiconductor chips 1C and a plurality of semiconductor chips 2C are provided on a substrate 40. The semiconductor chip 1C has, for example, an IGBT or a MOSFET. The semiconductor chip 2C has, for example, an FWD.

In the semiconductor chip 1C, the rear surface of a semiconductor layer 20 is recessed and a lower electrode 10 and a bonding member 30 are provided in the recessed portion.

Herein, the lower electrode 10 is positioned under an active region 1a of the semiconductor layer 20. The lower electrode 10 is not positioned under a termination region 1t of the semiconductor layer 20. The area of the lower electrode 10 is smaller than the area of an upper electrode 11.

In the semiconductor chip 1C, a portion of the semiconductor layer 20 is made into a frame member 20f. The frame member 20f is in contact with the substrate 40. When the semiconductor chip 1C is seen from a Z-direction, the frame member 20f surrounds the lower electrode 10 and the bonding member 30.

According to the semiconductor chip 1C, the bonding member 30 is surrounded by the frame member 20f. Accordingly, it is more difficult for the bonding member 30 to overflow from the space between the semiconductor chip 1C and the substrate 40.

In the semiconductor chip 2C, the rear surface of a semiconductor layer 21 is recessed and a lower electrode 12 and a bonding member 31 are provided in the recessed portion.

Herein, the lower electrode 12 is positioned under an active region 2a of the semiconductor layer 21. The lower electrode 12 is not positioned under a termination region 2t of the semiconductor layer 21. The area of the lower electrode 12 is smaller than the area of an upper electrode 13.

In the semiconductor chip 2C, a portion of the semiconductor layer 21 is made to be a frame member 21f. The frame member 21f is in contact with the substrate 40. When the semiconductor chip 2C is seen from a Z-direction, the frame member 21f surrounds the lower electrode 12 and the bonding member 31.

According to the semiconductor chip 2C, the bonding member 31 is surrounded by the frame member 21f. Accordingly, it is more difficult for the bonding member 31 to overflow from the space between the semiconductor chip 2C and the substrate 40.

### Fourth Embodiment

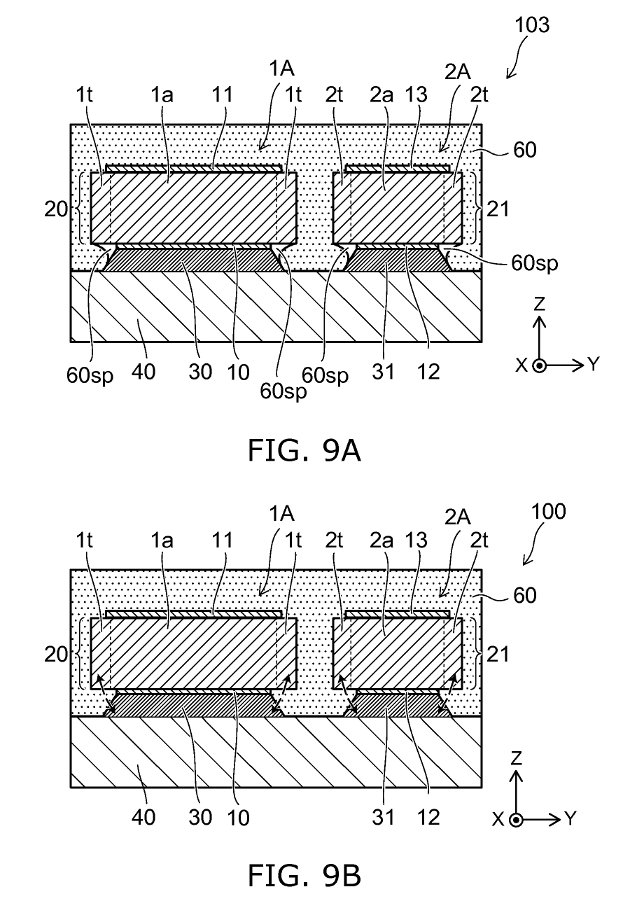

FIG. 9A is a schematic cross-sectional view showing a portion of an electronic component according to a fourth embodiment and FIG. 9B is a schematic cross-sectional view showing a portion of the electronic component according to the first embodiment.

In an electronic component 103 according to the fourth embodiment shown in FIG. 9A, a space 60sp exists between a substrate 40 and a semiconductor layer 20. In addition, the space 60sp exists between the substrate 40 and a semiconductor layer 21.

The gap between the substrate 40 and the semiconductor layer 20 and the gap between the substrate 40 and the semiconductor layer 21 are made to be narrow. For this reason, the space 60sp is formed between the substrate 40 and the semiconductor layer 20 or between the substrate 40 and the semiconductor layer 21 by adjusting the pressure while sealing with a sealing resin 60, the viscosity of the sealing resin 60, and the like.

In contrast, in the electronic component 100 according to the first embodiment, the space 60sp is not provided between the substrate 40 and the semiconductor layer 20. In addition, the space 60sp is not provided between the substrate 40 and the semiconductor layer 21.

Herein, the thermal expansion coefficient of the bonding members 30 and 31 is set to be 15×10⁻⁶/° C. to 24×10⁻⁶/° C. In addition the thermal expansion coefficient of the sealing resin 60 is set to be 7×10⁻⁶/° C. to 630×10⁻⁶/° C.

The following phenomenon can occur when the thermal expansion coefficient of the sealing resin 60 is higher than the thermal expansion coefficient of the bonding members 30 and 31, for example.

When the semiconductor chips 1A and 2A operate, in some cases, the semiconductor chips 1A and 2A generate heat and the temperature around the semiconductor chips 1A and 2A increases.

Herein, in the structure shown in FIG. 9B, in some cases, together with the temperature rise, the sealing resin 60 provided between the substrate 40 and the semiconductor layer 20 is preferentially heat-expanded and repulsive forces (arrows in the drawing) are applied to the semiconductor layer 20 and bonding member 30. Alternately, in some cases, together with the temperature rise, the sealing resin 60 provided between the substrate 40 and the semiconductor layer 21 is preferentially heat-expanded and repulsive forces (arrows in the drawing) are applied to the semiconductor layer 21 and the bonding member 31.

Such repulsive forces induce separation of the lower electrode 10 and the bonding member 30 and separation of the lower electrode 12 and the bonding member 31, and therefore, it is desirable to suppress the repulsive forces as much as possible.

In contrast, in the electronic component 103 shown in FIG. 9A, the space 60sp is provided between the substrate 40 and the semiconductor layer 20 and the space 60sp is provided between the substrate 40 and the semiconductor layer 21. Accordingly, the above-described thermal expansion of the sealing resin does not preferentially occur even if the temperature around the semiconductor chips 1A and 2A increases.

Accordingly, when the electronic components 100 and 103 are used over a long period of time, in the electronic component 103, the lower electrode 10 and the bonding member 30 rarely peel off and the lower electrode 12 and the bonding member 31 rarely peel off, compared to the electronic component 100.

The embodiments have been described above with reference to examples. However, the embodiments are not limited to these examples. More specifically, these examples can be appropriately modified in design by those skilled in the art. Such modifications are also encompassed within the scope of the embodiments as long as they include the features of the embodiments. The components included in the above examples and the layout, material, condition, shape, size and the like thereof are not limited to those illustrated, but can be appropriately modified.

Furthermore, the components included in the above embodiments can be combined as long as technically feasible. Such combinations are also encompassed within the scope of the embodiments as long as they include the features of the embodiments. In addition, those skilled in the art could conceive various modifications and variations within the spirit of the embodiments. It is understood that such modifications and variations are also encompassed within the scope of the embodiments.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor chip comprising:
a semiconductor layer;
an upper electrode provided on the semiconductor layer; and
a lower electrode provided under the semiconductor layer, the lower electrode being under an active region of the semiconductor layer, the lower electrode not being under a termination region of the semiconductor layer, an element being disposed in the active region, and the termination region being beside the active region.

2. The chip according to claim 1, wherein
the semiconductor layer includes:
a first semiconductor region of first conductivity-type provided between the upper electrode and the lower electrode,
a second semiconductor region of second conductivity-type provided between the lower electrode and the first semiconductor region,
a third semiconductor region of second conductivity-type provided between the upper electrode and the first semiconductor region, and
a fourth semiconductor region of first conductivity-type provided between the upper electrode and the third semiconductor region, and
the chip further comprising a gate electrode provided on the first semiconductor region, the third semiconductor region, and the fourth semiconductor region via an insulating film.

3. The chip according to claim 1, wherein
an area of the lower electrode is smaller than an area of the upper electrode.

4. The chip according to claim 1, further comprising:
a frame member provided under the semiconductor layer, and the frame member surrounding the lower electrode.

5. The chip according to claim 4, wherein
a thickness of the frame member is greater than a thickness of the lower electrode.

6. The chip according to claim 4, wherein
the frame member includes an insulating material or a semiconductor material.

7. An electronic component, comprising:
a substrate;
a first semiconductor chip and a second semiconductor chip provided on the substrate, the first semiconductor chip and the second semiconductor chip having a semiconductor layer, an upper electrode provided on the semiconductor layer, and a lower electrode provided under the semiconductor layer, the lower electrode being under an active region of the semiconductor layer, the lower electrode not being under a termination region of the semiconductor layer, an element being disposed in the active region, and the termination region being beside the active region;
a first bonding member provided between the substrate and the lower electrode of the first semiconductor chip; and
a second bonding member provided between the substrate and the lower electrode of the second semiconductor chip.

8. The component according to claim 7, wherein
the first bonding member and the second bonding member are stored between the semiconductor layer and the substrate.

9. The component according to claim 7, wherein
the first semiconductor chip includes a field-effect transistor.

10. The component according to claim 7, wherein
the second semiconductor chip includes a diode.

11. The component according to claim 7, further comprising a sealing resin sealing at least a portion of the substrate, the plurality of the semiconductor chips, and the bonding member, the sealing resin being provided between the semiconductor layer and the substrate.

12. The component according to claim 7, wherein
the first semiconductor chip and the second semiconductor chip have a frame member provided under the semiconductor layer, the frame member surrounds the lower electrode, and the frame member is in contact with the substrate, the frame member surrounds the bonding member.

13. The component according to claim 12, wherein
a thickness of the frame member is greater than a thickness of the lower electrode.

14. The component according to claim 12, wherein
the frame member includes an insulating material or a semiconductor material.

15. The component according to claim 7, wherein
a space exists between the substrate and the semiconductor layer.
